(19) United States
(12) Patent Application Publication
(10) Pub. No.: US 2020/0230643 A1
(43) Pub. Date: Jul. 23, 2020

(54) PERMEATION-BARRIER

(71) Applicant: Evatec AG, Trubbach (CH)

(72) Inventors: Rico Benz, Montlingen (CH); Stephan Voser, Buchs SG (CH); Jurgen Weichart, Balzers (LI)

(21) Appl. No.: 16/633,814

(22) PCT Filed: Jul. 12, 2018
(86) PCT No.: PCT/EP2018/068918

§ 371 Date: Jan. 24, 2020

(30) Foreign Application Priority Data
Jul. 27, 2017 (CH) 00977/17

(51) Int. Cl. B05D 1/00; C23C 16/40; C23C 16/455; C23C 14/56

(52) U.S. Cl. CPC B05D 1/62; C23C 14/568; C23C 16/45536; C23C 16/401

(57) ABSTRACT

The method of providing a permeation-barrier layer system on a substrate includes establishing a permeation seal by depositing, by PVD and/or by ALD, an inorganic material layer system, thereby providing adhesion of the inorganic material layer system and crack-sealing by depositing a polymer material layer system on the substrate and the inorganic material layer system on the polymer material system.

So as to realize a thin layer on a substrate, which effectively bars permeation, as of water molecules, towards and onto the substrate, such a permeation-barrier layer must be a layer of an inorganic material

### Definition

In the frame of the present description and claims, we understand under the term “substrate” a workpiece generically. The substrate may comprise material which is sensitive to temperature e.g. above 150° C. or lower. The substrate may have a plate-like shape. The substrate may be an electric device and may comprise printed circuit board material as an example of thermally sensitive material.

Organic material layers, e.g. of a polymer, e.g. most of the plasma-polymerized layers, have not sufficient sealing effect or necessitate large layer thicknesses to become effectively permeation-barring. With plasma enhanced CVD (PECVD), dense inorganic layers may be realized, often either at high temperatures e.g. above 150° C. and/or by the use of dangerous gases e.g. of silane.

Purely inorganic material layers have the drawback that they are brittle and that their temperature coefficient of expansion is not adapted to that of the starting substrate. Thereby already small increases of the temperature may lead to cracks of the inorganic material layer or to an impairment of adherence of the inorganic material layer to the starting substrate.

### Definition

We understand under the term “starting substrate” a substrate as defined above, which is yet untreated or not enough treated for barring permeation.

It is one object of the present invention to provide a substrate, which is permeation-protected, thereby avoiding the drawbacks as addressed above. This is achieved by a substrate comprising a starting substrate and a permeation-barrier layer system. The permeation-barrier layer system comprises a polymer material layer system, which latter comprises at least one plasma-polymerized polymer-material-containing layer and resides directly on the starting substrate. The permeation-barrier layer system further comprises an inorganic material layer system comprising at least one PVD-deposited or at least one ALD deposited inorganic-material-containing layer, deposited directly on the polymer material layer system.

### Definitions

we understand under a “polymer material layer system” a layer system, which comprises one or more than one “polymer-material-containing” layers. At least one of these layers “contains plasma-polymerized polymer-material”. If the “polymer material layer system” comprises more than one “polymer-material-containing” layers, some of these layers may be polymerized differently than by plasma. The layers may further contain, respectively, different polymer materials.
we thereby understand under a “polymer-material-containing” layer or under a “plasma-polymerized polymer-material-containing” layer a layer, which consists of polymer material or a layer of polymer material containing at least one residual material e.g. of inorganic material.
we understand under an “inorganic material layer system” a layer system, which comprises one or more than one “inorganic-material-containing” layers. At least one of these layers is PVD- or ALD-deposited. If the “inorganic material layer system” comprises more than one “inorganic-material-containing” layers some of these layers may be PVD deposited, some of these layers may be ALD deposited, some of these layers may even be deposited by processes different from PVD and ALD e.g. by CVD, PECVD etc. The layers may further contain or consist of, respectively, different inorganic materials.
we thereby understand under an “inorganic-material-containing” layer a layer, which consists of inorganic material or a layer of inorganic material containing at least one residual material e.g. of polymer material.

If we address the starting substrate with SS, the polymer material layer system with PP and the deposited inorganic material layer system with PVD/ALD, the minimal structure of the substrate is thus SS-PP-PVD/ALD.

The polymer material layer system thereby provides for good adherence of the PVD/ALD deposited layer system with respect to the starting substrate and seals possibly occurring cracks in the inorganic material layer system.

In one embodiment of the substrate according to the invention, the substrate further comprises at least one further polymer layer system—which comprises at least on further polymer-material-containing layer, which may be plasma-polymerized or not—and which is directly deposited on the PVD/ALD deposited inorganic material layer system. Thus, the structure becomes:

### SS-PP-PVD/ALD-PP.

If no further layer systems are provided, the further polymer material layer system provides for at least a part of that surface of the substrate, which is exposed to ambient or which is to be further treated.

In spite of the fact that already the polymer material layer system between the starting substrate and the PVD/ADL deposited, inorganic material layer system may suffice, in most cases the further or a further polymer material layer system is applied as the outermost layer system which, additionally to sealing cracks in the inorganic material layer system, is moisture- or liquid-repellant.

In one embodiment, the starting substrate itself comprises one or more than one starting substrate layers, and the polymer material layer system with at least one plasma-polymerized polymer-material-containing layer is deposited directly on the outermost of the addressed starting substrate layers.

In one embodiment of the substrate according to the invention, the starting substrate may be characterized by at least one of the following features:
it is, most generically a workpiece;
it has a plate-like shape;
it is an electric device;
it comprises thermally sensitive material, e.g. sensitive to temperatures above 150° C. or lower;
it comprises printed circuit board material.

In one embodiment of the substrate according to the invention, it comprises at least one further permeation-barrier layer system, which comprises a polymer material layer system—comprising at least one polymer-material-containing layer—and an inorganic material layer system, which comprises at least one PVD- or ALD-deposited inorganic-material-containing layer—and stapled in the indicated sequence on the one PVD/ALD-deposited inorganic material layer system. There results in fact a structure:

SS-PP-PVD/ALD-PP-PVD/ALD- . . . (PP).

Thus, there results, departing from the starting substrate SS, a polymer material layer system PP, directly upon the polymer material layer system an inorganic material layer system PVD/ALD, directly upon such inorganic material layer system, a polymer material layer system PP and directly upon the just addressed polymer material layer system again an inorganic material layer system PVD/ALD. This layer system sequence may be continued at the substrate according to the present invention depending upon the respective thicknesses of the addressed layer systems and barrier accuracy to be achieved. Again, in a good embodiment the outermost layer is a layer of a polymer material layer system (PP).

Thus, and in one embodiment of the substrate according to the invention, it comprises more than one of the permeation-barrier layer systems, stapled one upon the other.

In one embodiment of the substrate according to the invention, at least one inorganic-material-containing layer contains or is of silicon oxide.

In one embodiment of the substrate according to the invention it comprises at least one specifically applied interface between a polymer-material-containing layer and an inorganic-material-containing layer. The interface comprises polymer material of the polymer-material-containing layer as well as inorganic material of the inorganic-material-containing layer, which in an embodiment, is PVD- or ALD-deposited. Thus, the material of the addressed specifically manufactured interface becomes a so-called ormocer (organically modified ceramics). In one embodiment a complete layer and not just an interface may be of an ormocer.

In one embodiment of the substrate according to the invention, at least a part of the surface of the substrate is a surface of a polymer-material-containing layer. Thus, the structure may be shown as:

SS-PP-PVD/ALD- . . . PP.

In one embodiment of the substrate according to the invention, at least one or more than one or even all of the polymer-material-containing layers are plasma-polymerized layers.

In one embodiment of the substrate according to the invention, the plasma-polymerized polymer-material-containing layer or more than one, or all of the polymer-material-containing layers are polymerized from at least one of at least one gaseous and from at least one liquid material.

In one embodiment of the substrate according to the invention, at least one polymer-material-containing layer contains carbon. In one embodiment the at least one plasma-polymerized polymer-material-containing layer contains carbon.

It is to be understood that, if more than one polymer-material-containing layer is provided, such layers may be polymerized differently, some from a gaseous material, some from such a liquid material, respectively, and/or from different gaseous materials and/or from different liquid materials.

In one embodiment of the substrate according to the invention at least one polymer-material-containing layer contains silicon. Thereby and in one embodiment, the one plasma-polymerized polymer-material containing layer contains silicon.

One embodiment of the substrate according to the invention comprises a polymer-material-containing layer, in one embodiment a plasma-polymerized polymer-material-containing layer, deposited from at least one of tetramethylsilane (TMS), hexamethyldisiloxan (HMDS(O)), hexamethyldisilazan (HMDS(N)), tetraethylorthosilan (TEOS), acetylene, ethylene, possibly a mixture of at least two of these materials.

Silicon containing liquids as tetramethylsilane (TMS), hexamethyldisiloxan (HMDS(O)), hexamethyldisilazan (HMDS(N)), tetraethylorthosilan (TEOS) etc. are easy to handle and lead to layers with characteristics between silicon and cross-linked networks similarly to that of fused silica.

Hydrocarbons such as C2H2, C2H4 etc. as gases or as liquids form cross-link networks similarly to that of diamond-like carbon (DLC), which generically has good barrier effect.

In a further embodiment of the substrate according to the invention, at least one or more than or all inorganic-material-containing layers are of at least one material selected from the group: Silicon oxide, silicon nitride, aluminum oxide, aluminum nitride, titanium oxide, titanium nitride, tantalum oxide, tantalum nitride, hafnium oxide or respective oxynitrides or a mixture thereof.

Please note that especially if at least some or even all the inorganic-material-containing layers are deposited especially by PVD rather than by PECVD, deposition may depart from a well-defined solid material, be it the material of a sputtering target or a solid material to be evaporated. Even for ALD deposition, the precursor gas may result from sublimation of a well-defined solid material.

In one embodiment of the substrate according to the invention, at least one or more than one or all inorganic-material-containing layers are deposited by sputtering.

In one embodiment of the substrate according to the present invention, at least one or more than one or all inorganic-material-containing layers are deposited by evaporation, in a good embodiment by electron-beam evaporation. By making use of electron-beam evaporation, materials with high melting temperatures, such as silicon oxide, may be evaporated. Some of these layers may be deposited by sputtering, some by evaporating.

In one embodiment of the substrate according to the present invention, at least one, or more than one, or all inorganic-material-containing layers are deposited by ALD.

In one embodiment of the substrate according to the present invention, at least one, or more than one, or all inorganic-material-containing layers are deposited by plasma-enhanced ALD(PEALD).

Thereby the reactive gas is activated with the help of a plasma.

In one embodiment of the substrate according to the present invention, the at least one, or more than one, or all inorganic-material-containing layers are deposited in a first step by means of a precursor gas and in a remotely performed subsequent step by means of a reactive gas.

In one embodiment of the substrate according to the present invention, the at least one, or more than one, or all inorganic-material-containing layers are deposited in a first step and in a deposition area by means of a precursor gas and in a subsequent step, performed in this deposition area, by means of a reactive gas.

In one embodiment of the substrate according to the present invention, the at least one, or more than one, or all inorganic-material-containing layers are deposited with a precursor gas containing silicon and/or a metal and with a reactive gas.

In one embodiment of the substrate according to the present invention the at least one, or more than one, or all inorganic-material-containing layers are deposited with a precursor gas containing at least one of silicon, aluminum, titanium, tantalum, hafnium.

In one embodiment of the substrate according to the present invention the at least one, or more than one, or all inorganic-material-containing layers are deposited with a precursor gas and with a reactive gas, the reactive gas containing at least one of oxygen and of nitrogen.

In one embodiment of the substrate according to the present invention, the permeation-barrier layer system is a permeation-barrier layer system for water molecules.

In one embodiment of the substrate according to the invention, the permeation-barrier layer system is transparent for visible light.

In one embodiment of the substrate according to the invention, the permeation-barrier layer system is electrically isolating from the surface of the substrate to the surface of the starting substrate.

In one embodiment of the substrate according to the invention, at least one layer of the permeation-barrier layer system is electrically isolating.

Two or more embodiments of the substrate according to the invention and as addressed may be realized in combination, unless being in mutual contradiction.

The present invention is further directed to a layer deposition apparatus which comprises:
a substrate carrier;
at least one inorganic material layer deposition station comprising at least one PVD layer deposition chamber and/or at least one ALD layer deposition chamber, each comprising a source of an inorganic material;
at least one polymer deposition station comprising at least one plasma-polymerizing chamber with a feed-line system for monomer feeding and a plasma source;
a control unit constructed to control intermittent exposure of said substrate carrier to the deposition effect from said inorganic material layer deposition station and from said at least one polymer deposition station.

One embodiment of the layer deposition apparatus according to the invention comprises at least one cooling station.

In one embodiment of the layer deposition apparatus according to the invention at least one inorganic material layer deposition station comprises at least one ALD layer deposition chamber comprising a gas supply arrangement operationally and controllably flow-connected to at least a precursor reservoir containing a precursor and to a reactive gas reservoir containing a reactive gas.

In one embodiment of the layer deposition apparatus according to the invention at least one inorganic material layer deposition station comprises at least two ALD layer deposition chambers, one of the at least two ALD layer deposition chambers comprising a gas supply arrangement operationally and controllably connected to a precursor reservoir containing a precursor, the other of said ALD deposition chambers comprising a gas supply arrangement operationally and controllably flow-connected to a reaction gas reservoir, containing a reactive gas.

In one embodiment of the layer deposition apparatus according to the invention, a precursor gas from said precursor reservoir contains at least one of silicon and of a metal.

In one embodiment of the layer deposition apparatus according to the invention, the metal is at least one of aluminum, tantalum, titanium, hafnium.

In one embodiment of the layer deposition apparatus according to the invention the reactive gas contains at least one of oxygen and of nitrogen.

In one embodiment of the layer deposition apparatus according to the invention at least one inorganic material layer deposition station comprises at least one ALD layer deposition chamber, this ALD layer deposition chamber comprises a laser source, a gas supply arrangement operationally flow-connected to at least a precursor reservoir containing a precursor and to a reactive gas reservoir containing a reactive gas.

In one embodiment of the layer deposition apparatus according to the invention at least one inorganic material layer deposition station comprises at least two ALD layer deposition chambers, one of said at least two ALD layer deposition chambers comprising a gas supply arrangement operationally connected to a precursor reservoir containing a precursor, the other of said ALD deposition chambers comprising a laser source and a gas supply arrangement operationally connected to a reaction gas reservoir, containing a reactive gas.

In one embodiment of the layer deposition apparatus according to the invention at least one inorganic material layer deposition station comprises at least one PVD layer deposition chamber.

In one embodiment of the layer deposition apparatus according to the invention the PVD layer deposition chamber is a sputter layer deposition chamber.

In one embodiment of the layer deposition apparatus according to the invention the PVD layer deposition chamber is an evaporation chamber, in one embodiment an electron-beam evaporation chamber.

In one embodiment of the layer deposition apparatus according to the invention the PVD layer deposition chamber has a solid material source of at least one metal or metal alloy or of an oxide or of a nitride or of an oxynitride of such metal or metal alloy.

In one embodiment of the layer deposition apparatus according to the invention at least one inorganic material layer deposition station and at least one polymer deposition station are distant from each other and the substrate carrier is controllably movable from one of these stations to the next one of these stations, preferably in a vacuum environment.

In one embodiment of the layer deposition apparatus according to the invention at least one PVD layer deposition chamber and/or at least one ALD layer deposition chamber and/or at least one cooling chamber comprises a controllably sealable—for layer deposition operation—and openable—for substrate handling-deposition space, and a pumping port abutting in said controllably sealable and openable deposition space.

In one embodiment of the layer deposition apparatus according to the invention at least one plasma-polymerizing chamber with a feed-line system for monomer feeding and with a plasma source comprises a for layer deposition operation controllably sealable and for substrate handling openable deposition space and a pumping port abutting in said controllably sealable and openable deposition space.

In one embodiment of the layer deposition apparatus according to the invention at least one inorganic material layer deposition station and at least one polymer deposition station perform layer deposition in a common deposition area.

One embodiment of the layer deposition apparatus according to the invention comprises along a linear or along a generically curved or along a circular movement path of the substrate carrier, a sequence of more than one pair of an inorganic material layer deposition station and of a polymer deposition station.

One embodiment of the layer deposition apparatus according to the invention comprises along a linear or along a generically curved or along a circular movement path of the substrate carrier, a sequence of an inorganic material layer deposition station and of a polymer deposition station directly subsequent the inorganic material layer deposition station just addressed.

One embodiment of the layer deposition apparatus according to the invention comprises a cooling station directly succeeding an inorganic material layer deposition station.

One embodiment of the layer deposition apparatus according to the invention is a vacuum apparatus comprising at least one input load lock and at least one output load lock or at least one bidirectional input/output load lock.

In one embodiment of the layer deposition apparatus according to the invention, at least one inorganic material layer deposition station and at least one polymer deposition station are layer depositing into a common deposition area and the control unit is constructed to intermittently enable/disable the addressed stations.

In one embodiment of the layer deposition apparatus according to the invention at least one inorganic material layer deposition station and at least one polymer deposition station are depositing into mutually distant areas and the control unit is constructed to control a movement of the substrate carrier between said areas.

One embodiment of the layer deposition apparatus according to the invention is constructed to enable deposition by both an inorganic material layer deposition station and a polymer deposition station simultaneously in a common deposition area during a controlled transition time span.

In one embodiment of the layer deposition apparatus according to the invention the feed-line system is in controlled flow communication with a reservoir containing a liquid or a gaseous monomer material.

In one embodiment of the layer deposition apparatus according to the invention the feed-line system is in controlled flow communication with a reservoir containing a material comprising carbon.

In one embodiment of the layer deposition apparatus according to the invention the feed-line system is in controlled flow communication with a reservoir containing a material comprising silicon.

In one embodiment of the layer deposition apparatus according to the invention, the feed-line system is in controlled flow communication with a reservoir containing at least one of tetramethylsilane (TMS), hexamethyldisiloxan (HMDS(O)), hexamethyldisilazan (HMDS(N)), tetraethylorthosilan (TEOS), acetylene, ethylene.

In one embodiment of the layer deposition apparatus according to the invention the substrate carrier is constructed to simultaneously carry more than one substrate and/or more than one starting substrate.

In one embodiment of the layer deposition apparatus according to the invention all polymerizing chambers are plasma-polymerizing chambers.

One embodiment of the layer deposition apparatus according to the invention has at least one of the following features:
the substrate carrier is constructed to carry a batch of substrates and/or of starting substrates;
the substrate carrier is constructed to carry a plurality of single substrates and/or of single starting substrates;
the movement of the substrate carrier is a rotational movement around an axis remote from the substrates or starting substrates and/or around respective central axes of the substrates and/or starting substrates;
the substrate carrier is provided in a vacuum environment.

As addressed the vacuum layer deposition apparatus may comprise at least one cooling station.

Such cooling station is e.g. provided to cool down substrates just after having been subjected to the or to an inorganic material layer deposition station, especially with a PVD layer deposition chamber, or directly between being exposed to one inorganic material layer deposition station and before being subsequently exposed to a next inorganic material layer deposition station.

As was addressed at least one inorganic material layer deposition station and at least one polymer material deposition station, comprise, respectively, mutually distant, for deposition mutually sealed and separately pumped vacuum treatment chambers. The substrate carrier is controllably movable from one of the addressed stations to the next, thereby and in a good embodiment, in a vacuum environment.

Such an embodiment may e.g. comprise a rotatable disc-shaped or ring-shaped substrate carrier constructed to carry a multitude of single substrates along its periphery and from one station to the next station. Thereby, a yet untreated starting substrate is first subjected to the vacuum plasma-polymerizing station (PPS) and then subsequently to the inorganic material layer depositing station PVD/ALDS.

The sequence of stations along the moving path of the substrate carrier, which may be linear, curved or circular, becomes, in a minimum configuration:
PPS-PVD/ALDS

If, as addressed above cooling of the substrate is to be provided, the station structure becomes, addressing the cooling station by CS:
PPS-PVD/ALDS-CS

or
PPS-PVD/ALDS1-CS-PVD/ALDS2-CS
   wherein PVD/ALDS1 and PVD/ALDS2 indicate inorganic material layer deposition stations for depositing equal or different materials.

Subsequently, the substrate considered may be transported to a further polymer material depositing station and then subsequently and, if desired, to one or more than one further inorganic material depositing station and polymer material depositing stations, terminating the overall station sequence, in a good approach, always by a polymer-material depositing station.

One or more than one or all polymer material depositing stations may be plasma-polymerizing stations, in some cases, some or all plasma-polymerizing stations may be replaced by polymerizing stations not making use of vacuum plasma.

Thus, the following sequence of stations prevails:

PPS-PVD/ALDS-PPS-n*(PVD/ALDS-PPS-PVD/ALDS . . . )-PPS (n≥0).

If cooling is necessary with respect to all PVD/ALDS, then the sequence becomes:

PPS-PVD/ALDS-CS-PPS-n*(PVD/ALDS-CS-PPS-PVD/ALDS . . . )-PPS (n≥0).

As was addressed, the inorganic material depositing station and the polymer material depositing station, constructed e.g. as a vacuum plasma-polymerizing station, are provided in a common vacuum treatment chamber.

A batch processing system may be considered in which e.g. a carrier calotte for a multitude of substrates to be simultaneously treated is exposed to inorganic material deposition as well as to polymer material deposition.

If the inorganic material layer deposition station and the polymer material deposition station are mutually distant from each other either in a common vacuum treatment chamber or in separate, separately pumped treatment chambers, the control unit controls timing of the movement of the substrate carrier and possibly enabling/disabling the stations and thus of substrate exposure to the respective deposition effects.

One embodiment of layer deposition system comprises more than one pair or more than a pair of PVD layer deposition stations and polymerizing stations.

If the layer deposition apparatus is a vacuum apparatus and thus comprises respective input/output load locks all treatment and transport chambers or stations including possibly provided cooling stations are vacuum stations.

In that at least one PVD layer deposition chamber and/or at least one ALD layer deposition chamber comprises a—for deposition operation—controllably sealable and—for substrate handling—openable deposition space, and a pumping port abutting in the controllably sealable and openable deposition space and/or in that at least one plasma-polymerizing chamber with a feed-line system for monomer feeding and with a plasma source comprises a—for layer deposition operation—controllably sealable and—for substrate handling—openable deposition space and a pumping port abutting in the controllably sealable and openable deposition space mutual cross contamination of the respective deposition spaces is practically excluded.

The activating of the reactive gas in the ALD thus exploiting a PEALD deposition process significantly reduces processing time.

Please note, that in some cases of exploiting ALD, thereby also of PEALD, it might be necessary to expose the substrate first to a processing step in a reactive gas atmosphere, e.g. in an oxidizing atmosphere, so as to improve adherence of the layer subsequently deposited by ALD thereby, in an embodiment, by PEALD.

If not in contradiction, two or more embodiments of the apparatus according to the invention may be combined.

The present invention is further directed to a method of providing a permeation-barrier system on a starting substrate or of manufacturing a substrate which is provided with a surface permeation-barrier layer system. The method comprises
a) establishing permeation-seal by depositing by PVD and/or by ALD at least one inorganic-material layer system, comprising at least one inorganic-material-containing layer, upon a starting substrate;
b) providing adhesion of said inorganic material layer system to said starting substrate and crack-sealing of said inorganic material layer system, by depositing a polymer material layer system comprising at least one polymer-material-containing layer, directly on said starting substrate and depositing said inorganic material layer system directly on said polymer material layer system.

One variant of the method according to the invention comprises vacuum plasma-polymerizing the or at least one polymer-material-containing layer being deposited.

In one variant of the method according to the invention establishing the permeation-seal comprises plasma enhanced ALD.

In one variant of the method according to the invention, at least one layer is deposited to form from an electrically isolating layer.

In one variant of the method according to the invention, the permeation-barrier layer system is deposited to be transparent for visible light.

In one variant of the method according to the invention, the temperature at the starting substrate during the depositions does not exceed a predetermined value, does, in one variant, not exceed at most 150° C.

One variant of the method according to the invention comprises depositing a further polymer material layer system, comprising at least one polymer-material containing layer, directly on the inorganic material layer system.

One variant of the method according to the invention comprises vacuum plasma-polymerizing material of more than one polymer-material-containing layers.

One variant of the method according to the invention comprises repeating the steps a) and b).

One variant of the method according to the invention comprises depositing a further polymer material layer system, comprising at least one polymer-material-containing layer, directly on the last-deposited inorganic material layer system.

One variant of the method according to the invention comprises cooling the substrate after or during at least one of depositing an inorganic material layer system.

One variant of the method according to the invention comprises depositing an inorganic-material-containing layer of silicon oxide.

One variant of the method according to the invention comprises depositing in a controlled manner at least one material interface between depositing a polymer-material-containing layer and depositing an inorganic-material-containing layer, the interface being of a material which comprises polymer material of the deposited polymer-material-containing layer as well as inorganic material of the inorganic-material-containing layer.

One variant of the method according to the invention comprises depositing at least one polymer-material-containing layer from a gaseous or a liquid material.

One variant of the method according to the invention comprises depositing at least one polymer-material-containing layer from a material containing carbon.

One variant of the method according to the invention comprises depositing at least one polymer-material-containing layer from a material containing silicon.

One variant of the method according to the invention comprises depositing at least one polymer-material-containing layer from one of tetramethylsilane (TMS), hexamethyldisiloxan (HMDS(O)), hexamethyldisilazan (HMDS(N)), tetraethylorthosilan (TEOS), acetylene, ethylene.

One variant of the method according to the invention comprises depositing at least one inorganic-material-containing layer comprising or consisting of at least one of silicon oxide, silicon nitride, aluminum oxide, aluminum nitride, titanium oxide, titanium nitride, tantalum oxide, tantalum nitride, hafnium oxide or of a respective oxynitride.

One variant of the method according to the invention comprises depositing at least one inorganic-material-containing layer by sputtering or by evaporation or by electron beam evaporation or by ALD or by plasma enhanced ALD.

One variant of the method according to the invention comprises depositing at least one inorganic-material-containing layer by ALD in an ALD deposition chamber and feeding a precursor gas and a reactive gas to said ALD deposition chamber.

One variant of the method according to the invention comprises depositing at least one inorganic-material-containing layer by ALD in at least two subsequent ALD deposition chambers and feeding a precursor gas to the first of the at least two ALD deposition chambers and feeding a reactive gas to the second of the at least two subsequent ALD deposition chambers.

In one variant of the method according to the invention the precursor gas contains silicon or a metal.

In one variant of the method according to the invention the addressed metal is at least one of aluminum, tantalum, titanium, hafnium.

In one variant of the method according to the invention the reactive gas contains at least one of oxygen and of nitrogen.

One variant of the method according to the invention comprises depositing an inorganic-material-containing layer in at least one layer deposition space, sealing said at least one deposition space during said depositing and pumping said deposition space by means of a pump directly connected to said deposition space.

Thereby cross contamination into or from the deposition space for depositing the inorganic-material-containing layer is substantially reduced.

One variant of the method according to the invention comprises depositing a polymer-material-containing layer in a layer deposition space, sealing said deposition space during said depositing and pumping said deposition space by means of a pump directly connected to said deposition space.

Thereby cross contamination into or from the deposition space for depositing the polymer-material-containing layer is substantially reduced.

Clearly in one variant of the method according to the invention both deposition spaces, for depositing the inorganic-material-containing layer on one hand and for depositing the polymer-material-containing layer on the other hand, are respectively sealed during depositing operation and are separately pumped.

One variant of the method according to the invention comprises manufacturing the permeation barrier layer system suppressing permeation of water molecules.

One variant of the method according to the invention is performed in vacuum.

It must be noted that all embodiments of the substrate according to the invention, of the layer deposition apparatus according to the invention as well as of the method according to the invention may, respectively, be combined in any combination if not contradictory.

The invention shall now and as far as necessary for the skilled artisan, further be exemplified with the help of figures. They show:

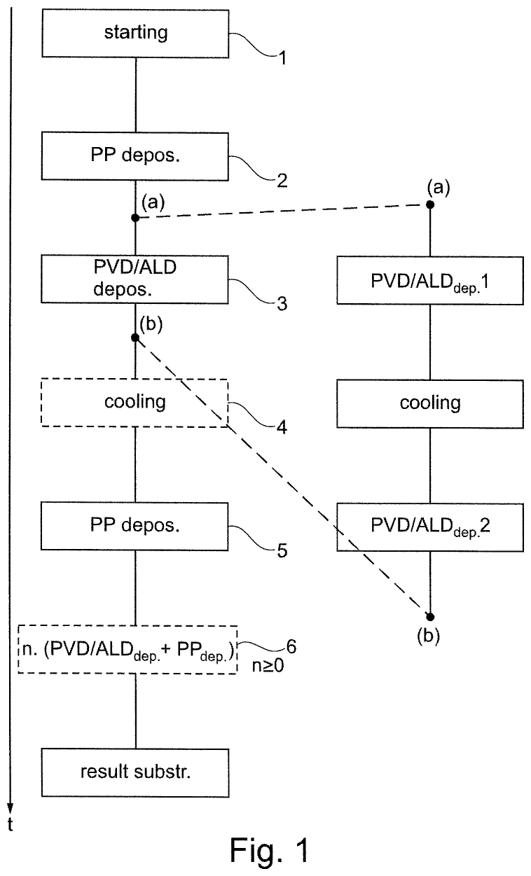

FIG. 1: a flowchart of the method according to the invention;

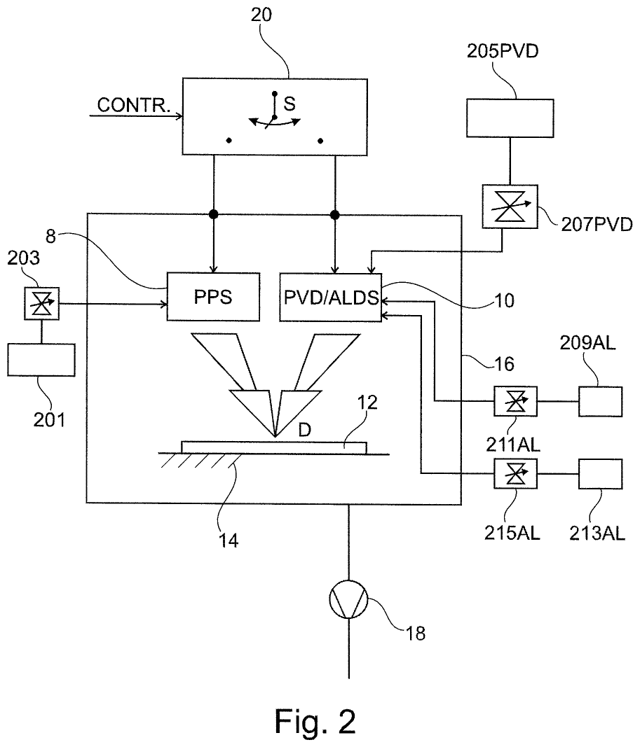

FIG. 2 to 6: schematically and simplified, embodiments of layer deposition systems according to the invention;

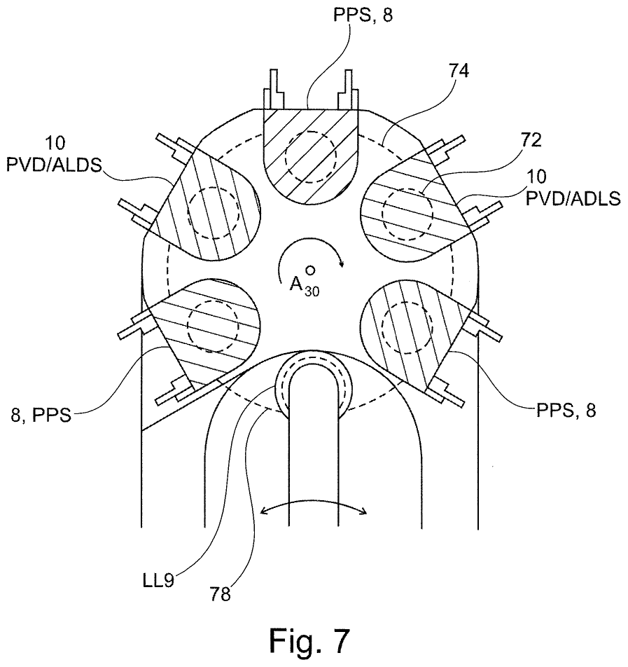

FIG. 7 schematically and simplified, a top view on a vacuum layer depositing system according to the invention;

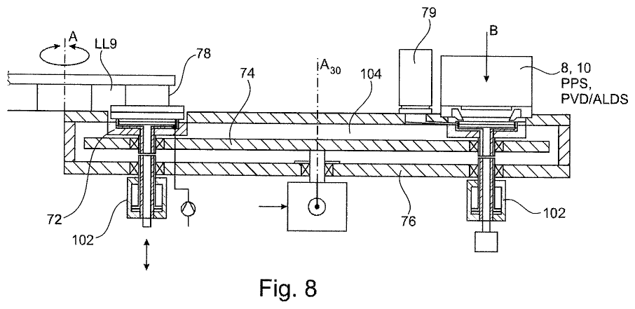

FIG. 8 schematically and simplified a cross section through the system of FIG. 7;

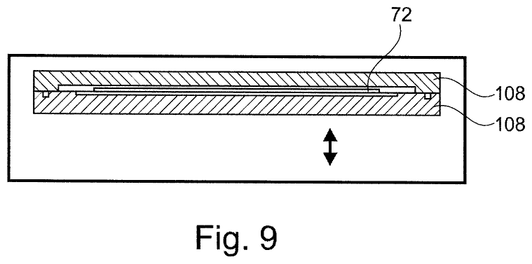

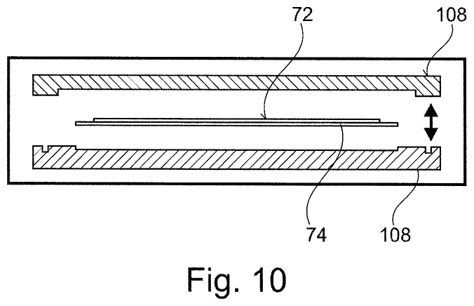

FIGS. 9 and 10: most schematically and simplified a cooling station in open and close position, as may be provided e.g. at the system of FIGS. 7 and 8;

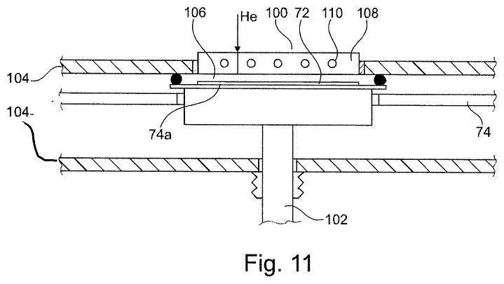

FIG. 11: schematically and simplified a cooling station integrated to the system according to FIGS. 7 and 8;

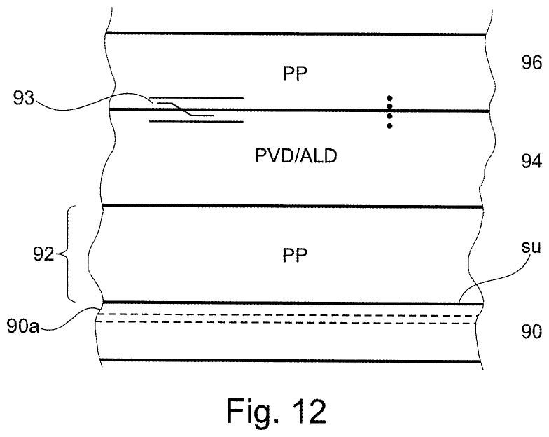

FIG. 12: Schematically a substrate according to the invention;

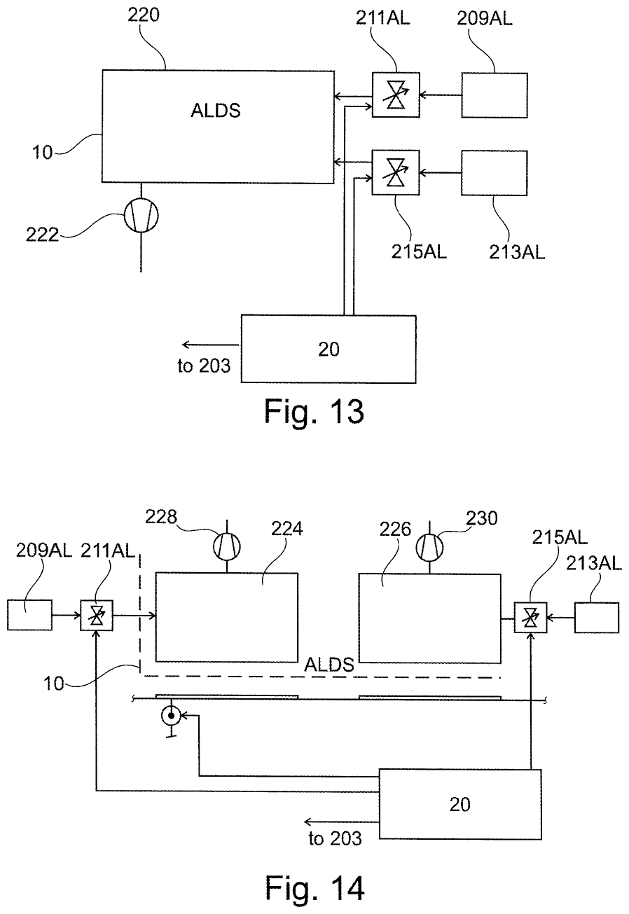

FIG. 13: schematically and simplified a one chamber ALD deposition station as applicable in the apparatus according to the invention;

FIG. 14: schematically and simplified a two chamber ALD deposition station as applicable in the apparatus according to the invention.

In FIG. 1 a flowchart of the method according to the invention, performed by a layer deposition apparatus according to the invention and resulting in a substrate according to the invention, is schematically shown over the time axis t.

In step 1 a starting substrate (before being treated according to the invention) or more than one starting substrates up to a batch of starting substrates is/are provided. In step 2 the one or more than one starting substrate is coated with a polymer-material-containing layer system PP which comprises at least one plasma-polymerized, polymer-material-containing layer. Thereby, and in a today favored embodiment, a gaseous or liquid monomer is plasma-polymerized resulting in at least one plasma-polymerized polymer layer directly deposited on the one or more than one starting substrate.

The liquid or gaseous or liquid monomer being polymerized contains carbon and, if liquid, silicon. As material to be polymerized, especially plasma-polymerized, TMS or HMDS(O) or HMDS(N) or TEOS or acetylene or ethylene may be used, whereby, if a polymer-material containing layer system with more than one polymer-material-containing layers is deposited, respectively different ones of the addressed monomers may be used one after the other or even a mixture thereof. Additionally, more than one or all of the polymer-material-containing layers may be realized by plasma-polymerization.

After deposition of the polymer-material-containing layer system, and in step 3, directly upon the polymer-material-containing layer system PP, an inorganic-material-containing layer system PVD/ALD is deposited, comprising at least one inorganic-material-containing layer. This is performed by a PVD (Physical Vapor Deposition) deposition or by an ALD (Atomic Layer Deposition) deposition. The deposited, inorganic-material-containing inorganic material layer system consists in a minimum configuration of a single inorganic-material-containing layer.

As PVD deposition methods sputtering, thereby magnetron sputtering or evaporation, may be used, thereby especially electron-beam evaporation. The respective PVD deposition method may be performed non-reactively or reactively. As an example, the inorganic material deposited in step 3 may be silicon oxide, silicon nitride, a metal oxide, a metal nitride, a metal oxynitride as e.g. aluminum oxide or aluminum nitride, titanium oxide, titanium nitride, tantalum oxide, tantalum nitride, hafnium oxide or a respective oxynitride.

If one or more than one of the inorganic-material-containing layers, or, in minimum configuration, the one inorganic-material-containing layer is deposited by ALD deposition, at least one precursor gas and at least one reactive gas are used, both fed either to one ALD treatment chamber or separately fed to subsequent ALD treatment chambers.

The reactive gas may thereby be activated by means of a plasma source resulting in plasma enhanced ALD.

The precursor gas contains, in one embodiment, at least one metal. The precursor gas may contain at least one of silicon, aluminum, tantalum, titanium, hafnium. The reactive gas may contain oxygen and/or nitrogen.

Please note that if the inorganic-material-containing layer system comprises more than one inorganic-material-containing layer, such layers may be deposited of different materials specifically, by PVD and/or ALD.

The inorganic-material-containing layer may also contain some amount of polymer-material, which in some applications, may even be desirable.

In an interface area, realized between a polymer-material-containing layer and an inorganic-material-containing layer, the material of inorganic material as well as polymer material may both be present.

As the specific temperature expansion coefficient of the starting substrate is customary quite different from the temperature expansion coefficient of the at least one inorganic-material-containing layer system PVD/ALD as deposited in step 3, the polymer-material-containing layer system PP deposited in step 2 provides for good adhesion of the inorganic-material-containing layer system PVD/ALD and seals possibly occurring cracks in the brittle inorganic-material containing layer system PVD/ALD.

In some applications of the present invention the starting substrate should not be loaded with high temperatures exceeding a definite value, e.g. of 150° C. or of below. Thus, as an example, printed circuit board material, as material of the starting substrate, should not be treated at temperatures exceeding 150° C.

In such cases, deposition of the PVD/ALD system with respectively thick inorganic-material-containing layers may result, without additional measures, in thermally overloading the starting substrates by exceeding the allowed temperatures.

Therefor and in such cases, there is provided, as shown in FIG. 1 in dashed lines by step 4, a cooling step following the step 3 of inorganic-material-containing layer system PVD/ALD deposition. Alternatively, or additionally and as schematically shown at the right-hand side of FIG. 1, the deposition of the inorganic-material-containing layer system PVD/ALD may be divided in more than one deposition sub-steps as of PVD/ALD1, PVD/ALD2 etc., and a cooling step may be introduced between subsequent PVD/ALD system deposition sub-steps. As the deposited inorganic-material-containing layer system may comprise more than one inorganic-material-containing layer of equal or of different inorganic materials, the PVD/ALD1, PVD/ALD2 etc. steps may be deposition steps for different or equal inorganic materials, thereby possibly making selectively use of PVD and ALD deposition.

After the termination of step 3, possibly cooling step 4, according to FIG. 1, there results a substrate comprising a starting substrate, directly deposited thereon, a polymer-material-containing layer system PP, as of step 2, and, directly on the polymer-material-containing layer system PP, a PVD and/or ALD deposited inorganic-material-containing layer system PVD/ALD as deposited by step 3. For some applications, already this substrate may be good enough for further use as the combination of the one polymer-material-containing layer system PP and of the inorganic-material-containing layer system PVD/ALD already provides for a permeation-barrier system.

Nevertheless, in most cases, there is further applied, according to step 5 in FIG. 1 upon the inorganic-material-containing layer system PVD/ALD, as deposited in step 3, a further polymer-material-containing layer system PP, which is deposited as explained in context with step 2. The substrate resulting from step 5 is customary the minimum configuration, as the polymer-material-containing layer system PP deposited in step 5 provides for an additional permeation-seal and for a layer which absorbs respective molecules, the permeation thereof having to be suppressed, especially water molecules.

Nevertheless, after deposition step 5, one or more than one pairs of inorganic-material-containing layer systems—PVD/ALD—and of polymer-material-containing layer systems-PP may be deposited as addressed in FIG. 1 in dashed lines by step 6, whereby that layer, which finally forms the outermost surface of the resulting substrate, is a polymer-material-containing layer. Clearly and if necessary, after or during respective deposition steps of inorganic-material-containing systems PVD/ALD, a cooling step is performed in analogy to the explanations given with deposition at step 3.

As was addressed, the step sequence as explained with the help of FIG. 1 is performed according to the present invention irrespective from the configuration of the layer deposition apparatus, which performs such sequence of treatment steps.

For most applications of the addressed method, the overall layer system as deposited is electrically insulating considered between the outermost surface of the resulting substrate and the surface of the starting substrate, whereupon the first PP layer system is deposited. Thus e.g. at least one of the deposited layers is electrically insulating.

Further and again for frequent applications of the method, the overall stack of layers is transparent for visible light, possibly also the starting substrate.

Today the polymer-material-containing layer system PP and the inorganic-material-containing layer system PVD/ALD have a total thickness between 50 nm and 300 nm.

In the following table different process flows are exemplified performed according to the method as explained with the help of FIG. 1 and resulting in substrates according to the invention. Thereby ALD-a addresses the ALD deposition step with the at least one precursor gas and ALD-b addresses the subsequent reacting step in the reactive gas atmosphere, in one embodiment improved by the plasma of a plasma source. Please note, that in the process flows 5, 6 and 8 both ALD steps ALD-a and ALD-b are performed in a single processing station, whereas according to the process flow 7 these ALD steps are performed in different processing stations. The indication n* addresses that the sequence in the frame may be repeated more than once.

For some material combinations it might be advisable to perform a treatment step in a reactive gas atmosphere, possibly plasma enhanced, before performing the ALD-a step, so as to improve adherence of the ALD deposited layer. This in analogy to performing the ALD-b step.

So as to minimize cross-contamination of treatments steps, at least some of the respective treatment chambers, especially chambers for PP deposition and/or for PVD deposition and/or for ALD deposition and/or for cooling are separately pumped and—during deposition-operation—sealed.

Most schematically and simplified, FIG. 2 shows an embodiment of a layer deposition system, here a vacuum layer deposition system, which performs the step sequence or process flows as was addressed in context with FIG. 1.

In the embodiment of FIG. 2 there is provided a vacuum plasma-polymerizing station PPS 8 and an inorganic material deposition station PVD/ALDS 10. Both stations 8 and 10 perform respective layer deposition on a starting substrate 12 on a substrate carrier 14. Thereby, both layer depositions are performed in a common vacuum treatment chamber 16 and in a common area D, as schematically shown. The treatment chamber 16 is pumped by a pumping arrangement 18.

The plasma-polymerizing station 8 is supplied in a controlled manner from a monomer source 201 containing a gaseous or liquid monomer material, controlled, as schematically shown, via a valve arrangement 203.

If the inorganic material deposition station 10 is a PVD deposition station, dependent whether the deposition is performed merely from a solid material source e.g. merely from a sputtering target, or is performed including reacting material from a solid material source with a reactive gas or gas mixture, the inorganic material deposition station 10 is supplied with a reactive gas or gas mixture as schematically shown at 205 PVD, controlled, as schematically shown, by a valve arrangement 207 PVD.

If the inorganic material deposition station 10 is an ALD deposition station, precursor gas is supplied in a controlled manner, as schematically shown, from a tank arrangement 209AL to the deposition station 10, via a valve arrangement 211AL. Additionally deposition, a reactive gas or gas mixture is supplied from a tank arrangement 213AL to the deposition station 10, in a controlled manner, as schematically shown by a valve arrangement 215AL.

To perform the time sequence of FIG. 1 a control unit 20 is provided, which enables, as schematically shown by switch S, either the plasma-polymerizing station 8 or the PVD/ALD deposition station 10 and thereby (not shown) controls the time sequence of respective gas supply by controlling the valve arrangements 203 and possibly 207 PVD or 203 and 211AL and 215AL. It might be necessary to flush the treatment chamber 16 with a flushing gas (not shown), between supplying monomer material and supplying a reactive gas for a reactive PVD deposition process or between supplying monomer material, supplying precursor gas and/or supplying reactive gas to the ALD deposition process.

This structure of the combined plasma-polymerizing PPS station and of the inorganic material deposition station PVD/ALDS is especially suited, if batches of starting substrates have to be treated, i.e. comprising a multitude of starting substrates arranged e.g. on a dome- or calotte-shaped, revolving substrate-carrier within the chamber 16. The substrates on such a carrier may additionally be rotated around a substrate central axis. Thereby, especially in this case, it might be advantageous to perform a PVD inorganic material deposition by evaporation, especially, and dependent from the solid material to be evaporated, by means of electron-beam evaporation.

A liquid or gaseous monomer material is fed into the treatment chamber 16 nearby the substrate carrier and is plasma-polymerized by means of a plasma source. The crucible material to be evaporated may be protected from polymer material by an arrangement of movable shutters during operation of the PPS station and, inversely, during operation of PVDS station, the plasma source may be protected from inorganic material deposition by respective movable shutters.

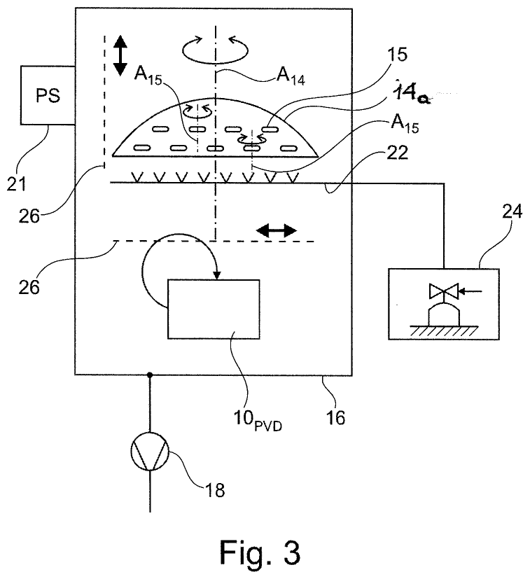

FIG. 3 shows schematically an embodiment as was just addressed. The inorganic material deposition station 10 is realized by an electron-beam evaporation station 10_{PVD}. The plasma-polymerization station 8 is realized by a plasma source 21 and a monomer feed-line system 22 which is in controlled flow communication with a tank arrangement 24 containing one or more than one gaseous or liquid monomer as was addressed above. The substrate carrier 14 is realized by a batch carrier dome or calotte 14a revolving about its central axis A14. The substrates 15 on the batch carrier 14 may additionally be rotated around respective substrate central axes A₁₅.

As shown in dashed lines at 26, a movable shutter arrangement may be provided to respectively protect the station 10_{PVD} as well as the plasma source 21 during disabled cycles.

In this case, making use of evaporation for inorganic material deposition may not necessitate a cooling step as was addressed in FIG. 1.

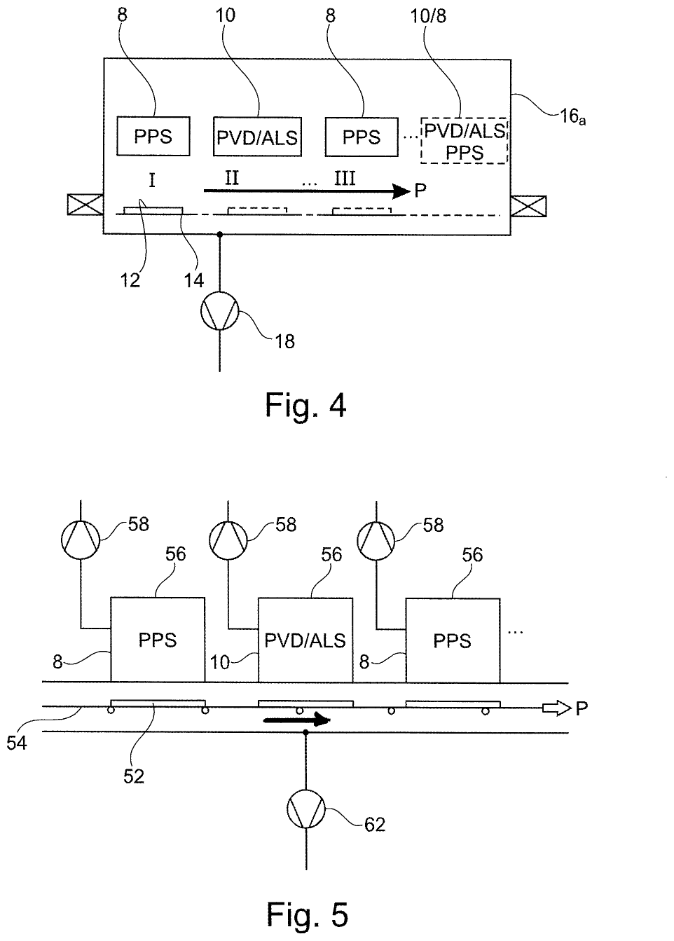

FIG. 4 shows, again most simplified and schematically, a further structure embodiment of a layer deposition apparatus according to the invention, again realized as a vacuum layer deposition apparatus, performing the method or step-sequence as was addressed in context with FIG. 1.

In opposition to the embodiment of FIGS. 2 and 3, in the embodiment of FIG. 4, the PPS station 8 and the PVD/ALDS station, 10 perform deposition into different deposition areas as indicated by I, II, III. The starting substrates 12 or the sequence of starting substrates 12 is transported by the substrate carrier 14 from one deposition area e.g. I to the next one e.g. II. As shown in dashed lines, along the travel path P of the substrates 12 and as was already addressed in context with FIG. 1, the last station which performs layer deposition on the substrates, is advantageously a PPS station 8. Although performing deposition into different deposition areas I, II . . . , the deposition stations 8, 10 etc. operate in a common overall treatment chamber 16a. In opposition to the embodiment of FIGS. 2 and 3 the substrates 12 are moved from one deposition station to the next and the substrate carrier is accordingly movable in a controlled manner along a linear or along a generically curved or along a circular path P. The control unit (not shown in FIG. 4) controls possible intermittent enablement of the deposition stations and the transport movement of the substrate carrier 14.

This embodiment structure is especially suited for single substrate treatment and the inorganic material deposition station or stations 10 is/are realized, in a good embodiment, either by respective sputtering sources or by ALD. In this case, cooling as was addressed in context with FIG. 1, may become necessary. If necessary and with an eye on FIG. 1, a cooling station (not shown in FIG. 4) is provided downstream the inorganic material deposition station 10 or subsequent any such additional station 10 as provided, especially if sputtering is applied.

Please note that the respective controlled supplies of gases or of liquid and the timing control unit controlling the time sequence of these supplies are not shown in FIG. 4,5 to 8, but are realized in analogy to the embodiment of FIG. 2.

A today favored structure of the layer deposition apparatus, again realized as a vacuum layer deposition apparatus, and according to the invention, is schematically and most simplified shown in FIG. 5.

In the structure embodiment of FIG. 5, the one or more than one PPS polymer deposition stations 8 and the one or more than one inorganic material deposition stations PVD/ALDS, 10 as well as one or more than one cooling stations possibly provided (not shown in FIG. 5) according to the explanations with respect to FIG. 1, are provided by respective treatment chambers 56 which are separately pumped as schematically shown by the pumps 58 and thus also mutually sealed in respective operating state. The substrate carrier 54, caring a multitude of substrates 52, is controllably movable along track P which may be linear, curved or, in an embodiment, circular. The substrate carrier 54 operates in a vacuum transport chamber 60 pumped by a pumping arrangement 62.

Especially if inorganic layer deposition is performed by PVD, thereby especially by sputtering, provision of cooling steps and accordingly of cooling chambers or cooling stations as was addressed in context with FIG. 1, might become necessary when treating starting substrates or more generically substrates, which are thermally sensitive.

If the deposition of inorganic material or one of the depositions of inorganic material is performed by ALD, principally two methods are possible, as now addressed with an eye on FIG. 13 and FIG. 14.

According to the embodiment of FIG. 13 the deposition station 10, realized as an ALDS deposition station, comprises a single treatment chamber 220 pumped by a pumping arrangement 222. The precursor gas as well as the reactive gas are both fed to the treatment chamber 220. Thereby the precursor gas is fed to the treatment chamber 220 from gas tank arrangement 209AL via controlled valve arrangement 211AL and reactive gas is fed to the treatment chamber 220 from gas tank arrangement 213AL via controlled valve arrangement 215AL. Time sequence of the respective gas feeds and (not shown) possibly of a supply of a flushing or rinsing gas, is controlled by the timing control unit 20.

According to the embodiment of FIG. 14 the deposition station 10, realized as deposition station ALDS, comprises at least two treatment chambers 224 and 226, each pumped by respective pumping arrangements 228 and 230. To minimize cross-contamination the chambers are, in operation, mutually sealable. The precursor gas is fed to the treatment chamber 224 from gas tank arrangement 209AL via controlled valve arrangement 211AL. The reactive gas is fed to the treatment chamber 226 from gas tank arrangement 213AL via controlled valve arrangement 215AL. Time sequence of the respective gas feeds and (not shown) possibly of a supply of a flushing or rinsing gas, is controlled by the timing control unit 20.

In all embodiments, where deposition of polymerized material is performed in a deposition area remote from a deposition area for depositing the inorganic material, the station 10 realized as ALDS station may be constructed according to FIG. 13 or according to FIG. 14.

The generic structure of the vacuum layer deposition apparatus according to the invention and thereby also according to FIG. 4 or FIG. 5 may be realized in different more specific structures. The substrates may or may not be rotated (not shown) around their central axes in analogy to A₁₅ in FIG. 3.

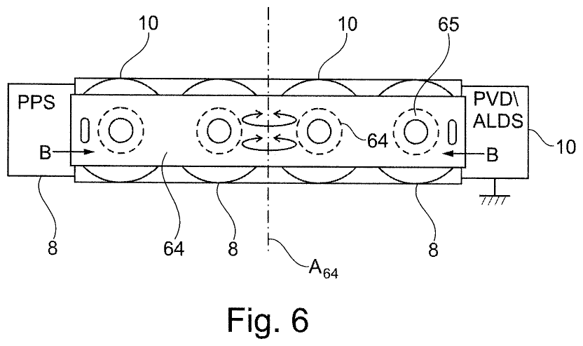

One more specific apparatus structure is schematically shown in FIG. 6. Here, the substrate carrier 64 is a carrousel or a drum, controllably rotatable about an axis A64. The substrates 65 are arranged and held along the periphery of the substrate carrier 64 with their substrate planes parallel to the axis A64.

The PPS stations 8 and the inorganic material deposition stations 10, PVD/ALDS are provided stationary along the trajectory path of the revolving substrate carrier 64. The azimuthal spacing of the stations accords with the azimuthal spacing of the substrates on the substrate carrier 64. The deposition stations 8,10 are arranged with main deposition directions B radially with respect to the axis A64. Clearly, and if necessary, one or more than one cooling stations are provided, and (not shown) an arrangement of input/output load lock. The stations of the embodiment of FIG. 6 may be separately pumped as of the embodiment of FIG. 5 and are thus mutually sealable or may be provided in a common vacuum vessel surrounding stationary the substrate carrier 64, which accords with the general representation of FIG. 4. Here too the substrates may be rotated around central axes in analogy to axes A₁₅ in the apparatus structure of FIG. 3.

In a today favored structure, the vacuum layer deposition apparatus is structured as disclosed in applicants' WO 2010/105967. The deposition steps, especially a PVD inorganic material layer deposition step, may be split in two or more than two equal deposition steps performed at respective stations, possibly with interconnected cooling stations. With respect to a general approach of process-splitting we may refer to the disclosure in applicants' WO 2010/106012.

Such a today favored vacuum layer deposition apparatus is nevertheless shown in the embodiment of FIGS. 7 and 8, schematically and simplified. Single substrates 72 are carried on a disc-shaped substrate carrier 74 as shown in the simplified cross-sectional representation of FIG. 8.

The substrates 72 are deposited on the substrate carrier 74 with substrate planes perpendicular to a rotational axis A₃₀ of the substrate carrier 74. Aligned with the circular path of the substrates 72 on the substrate carrier 74, there are provided, as shown in FIG. 7, the respective number of PPS stations 8 and PVD/ALDS stations 10 with main direction B of deposition parallel to the axis A₃₀. The substrate carrier 74 operates in a vacuum transport chamber 76. The stationary stations 8 and 10 have an azimuthal spacing which is equal to the azimuthal spacing of the substrates 72 on substrate carrier 74. There is provided a bi-directional load-lock station LL 9, at which untreated starting substrates are fed e.g. from ambient into the vacuum transport chamber 76 and on the substrate carrier 74, whereas treated substrates are unloaded from the substrate carrier 74 e.g. into ambient.

Please note that the stations 8,10 are separately pumped by pumps 79 and are mutually sealable by controllably lifting the substrates 72 by means of lift arrangements 102 from the substrate carrier 74 into engagement with sealing frames, thereby sealing the respective deposition chamber.

If the deposition of inorganic material is performed by ALD and the respective deposition station 10 is realized according to the embodiment of FIG. 14, then in the embodiments of FIGS. 4,5,6,7 and 8 the respective ALDS station is realized by at least two subsequently served, separately pumped and mutually sealable treatment chambers.

With the exception of providing deposition stations according to the present invention, the WO 2010/106012 discloses a general structure of an apparatus which may be used in context with the present invention.

If it is necessary and as was addressed already in context with FIG. 1, to provide cooling of the substrates after or during PVD inorganic layer deposition, cooling chambers similar to those discussed in applicants WO 2016/091927 are integrated in the apparatus as addressed in context with FIGS. 5 to 8, 13, 14.

In the WO 2016/091927 a cooler vacuum chamber is disclosed. The cooler chamber is schematically shown in FIGS. 9 (close position) and 10 (open position). Such principle of a cooler chamber is perfectly suited to be integrated as one or more than one cooling chambers in the system as shown especially in the FIGS. 7 and 8. This vacuum cooling chamber may be pressurized with a heat conducting gas e.g. with helium, to significantly rise heat transfer from the substrates to the enclosing walls of the clam-type cooling chamber, which are cooled.

FIG. 11 shows most schematically and simplified, a possible approach of integrating such cooling chamber or -station in the apparatus as shown in the FIGS. 7 and 8.

At such cooling station 100, the substrate 72 is lifted from the substrate carrier 74 by a lift arrangement 102 as also provided to cooperate with the deposition stations or chambers, see FIGS. 7 and 8. With respect to the vacuum transport chamber 104 for the substrate carrier 74, lifting of the substrate 72 establishes a thin sealed cooling compartment 106, wherein the substrate 72 resides close to a cooling clam-member 108. At least one cooling member 108 is cooled e.g. by means of a liquid cooling medium, circulating in a cooling channel system 110. A heat conduction gas, e.g. helium, may be supplied into the cooling compartment 106. That part 74a of the substrate carrier 74, which is liftable and which holds the substrate 72 is cooled by direct contact to the lift arrangement 102, which, if necessary may be actively cooled as well.

If multiple pairs of polymerized-material-containing layer systems and of inorganic material containing layer system have to be deposited on the starting substrate, it might be necessary to perform the deposition of these systems more than once i.e. to repeat deposition cycle at least once. This may be performed by more than one 360° rotation of the substrate carrier 74 of FIGS. 7 and 8 or 64 as of FIG. 6.

In FIG. 12 there is shown, most schematically, a substrate with a permeation-barrier layer system according to the present invention and manufactured according to the method of the invention.

A starting substrate 90 may be or may not be already covered by thin layers as shown in dashed lines at 90ₐ. The starting substrate 90 is directly covered along at least a part of its extended surface Su by a layer system PP 92 of plasma-polymerized material. The PP layer system 92 of plasma-polymerized material may be single-layered or multi-layered, whereby more than one layer of different polymerized materials may be part of the polymerized material layer system 92.

Directly on the PP layer system 92 containing polymerized material there is provided an inorganic-material-containing layer system 94 of PVD- and/or ALD-deposited inorganic material or materials. Again, the inorganic-material-containing layer system 94 may consist of a single PVD or ALD-deposited, inorganic material layer or of more than one PVD and/or ALD-deposited inorganic material layers of equal or of different inorganic materials.

In a minimum substrate configuration, the outermost layer of system 96 is a layer of polymerized material. The layer system 96 directly resides on an inorganic material layer system 94.

With an eye back on FIG. 1, it is possible when transiting from PP deposition to a PVD or ALD deposition or, inversely, from PVD or ALD deposition to PP deposition, to provide a transition time span, in which the polymer material as well as the inorganic material are simultaneously deposited, namely by operating the respective deposition stations during this time span simultaneously and in a same deposition area.

With an eye on FIG. 12 this results in material interface zones 93, in which an inorganic material as well as a polymerized material are present with varying concentration. The minimum structure according to FIG. 12 may further be provided with further PVD and/or ALD deposited inorganic-material-containing layer systems and with further PP polymerized-material-containing layer systems, i.e. in sequences upon the layer system 96 e.g. according to:
PVD/ALD-PP-PVD/ALD- . . . PP . . . .

Generically it might be advantageous to provide in a layer of inorganic material e.g. deposited by ALD, some amount of polymerized material.

If the overall layer system 92,94,96, etc. is to be electrically insulating this may be realized by providing one or more than one of the layers sufficiently electrically insulating.

Further all the layers applied on the starting substrate may be selected to be transparent for visible light.

### For Disclosure Purpose of all Aspects of the Invention these Aspects are Summarized Below

1) A substrate comprising:
   a starting substrate;
   a permeation-barrier layer system comprising:
      a polymer material layer system, comprising at least one plasma-polymerized polymer-material-containing layer and residing directly on said starting substrate;
      an inorganic material layer system comprising at least one PVD- or at least one ALD-deposited inorganic-material-containing layer, deposited directly on said polymer material layer system.
2) The substrate of aspect 1 further comprising at least one further polymer layer system, comprising at least one further polymer-material-containing layer, and deposited directly on said inorganic material layer system.
3) The substrate of one of aspects 1 or 2, wherein said starting substrate comprises one or more than one starting substrate layers and said polymer material layer system is deposited on the outermost of said starting substrate layers.
4) The substrate of one of aspects 1 to 3, wherein said starting substrate has at least one of the following features:
   it is, most generically, a workpiece;
   it has a plate-like shape;
   it is an electric device;
   it comprises thermally sensitive material, e.g. sensitive to temperatures above 150° C. or lower;
   it comprises printed circuit board material.
5) The substrate of one of aspects 1 to 4 comprising at least one further of said permeation-barrier layer system residing directly on said one permeation-barrier system.
6) The substrate of one of aspects 1 to 5 at least one inorganic-material-containing layer containing or consisting silicon oxide.
7) The substrate of one of aspects 1 to 6 comprising at least one interface between a polymer-material-containing layer and an inorganic-material-containing layer, said interface comprising inorganic material of said inorganic-material-containing layer as well as polymer material of said polymer-material-containing layer.
8) The substrate of one of aspects 1 to 7, wherein a surface of said substrate is a surface of a polymer-material-containing layer.
9) The substrate of one of aspects 1 to 8 comprising more than one polymer-material-containing layer and more than one or all polymer-material-containing layers are plasma-polymerized layers.
10) The substrate of one of aspects 1 to 9 said at least one plasma-polymerized layer or more than one, or all polymer-material-containing layers being polymerized from at least one of at least one gaseous and of at least one liquid material.
11) The substrate of one of aspects 1 to 10 at least one polymer-material-containing layer containing carbon.
12) The substrate of one of aspects 1 to 11, said at least one polymer-material-containing layer containing carbon.
13) The substrate of one of aspects 1 to 12 at least one polymer-material-containing layer containing silicon.
14) The substrate of one of aspects 1 to 13 said plasma-polymerized polymer-material-containing layer containing silicon.
15) The substrate of one of aspects 1 to 14 comprising a polymer-material-containing layer deposited from at least one of tetramethylsilane (TMS), hexamethyldisiloxan (HMDS(O)), hexamethyldisilazan (HMDS(N)), tetraethylorthosilan (TEOS), acetylene, ethylene.
16) The substrate of one of aspects 1 to 15 comprising a plasma-polymerized polymer-material-containing layer deposited from at least one of tetramethylsilane (TMS), hexamethyldisiloxan (HMDS(O)), hexamethyldisilazan (HMDS(N)), tetraethylorthosilan (TEOS), acetylene, ethylene.
17) The substrate of one of aspects 1 to 16 wherein at least one inorganic-material-containing layer contains at least one material selected from the group: Silicon oxide, silicon nitride, aluminum oxide, aluminum nitride, titanium oxide, titanium nitride, tantalum oxide, tantalum nitride, hafnium oxide or the respective oxynitrides or a mixture thereof.
18) The substrate of one of aspects 1 to 17 at least one, or more than one, or all inorganic-material-containing layers being deposited by sputtering.
19) The substrate of one of aspects 1 to 18 at least one, or more than one, or all the inorganic material layers being deposited by evaporation, preferably by electron-beam evaporation.
20) The substrate of one of aspects 1 to 19 at least one, or more than one, or all inorganic-material-containing layers being deposited by ALD.
21) The substrate of one of aspects 1 to 20 at least one, or more than one, or all inorganic-material-containing layers being deposited by plasma-enhanced ALD (PEALD).
22) The substrate of one of aspects 20 or 21 said at least one, or more than one, or all inorganic-material-containing layers being deposited in a first step by means of a precursor gas and in a remotely performed subsequent step by means of a reactive gas.
23) The substrate of one of aspects 20 or 21 said at least one, or more than one, or all inorganic-material-containing layers being deposited in a first step and in a deposition area by means of a precursor gas and in a subsequent step, performed in said deposition area, by means of a reactive gas.
24) The substrate of one of aspects 20 to 23 said at least one, or more than one, or all inorganic-material-containing layers being deposited with a precursor gas containing silicon and/or a metal and with a reactive gas.
25) The substrate of one of aspects 20 to 24 said at least one, or more than one, or all inorganic-material-containing layers being deposited with a precursor gas containing at least one of silicon, aluminum, titanium, tantalum, hafnium.
26) The substrate of one of aspects 20 to 25 said at least one, or more than one, or all inorganic-material-containing layers being deposited with a precursor gas and with a reactive gas said reactive gas containing at least one of oxygen and of nitrogen.
27) The substrate of one of aspects 1 to 26 wherein said permeation-barrier layer system is a permeation-barrier layer system for water molecules.
28) The substrate of one of aspects 1 to 26, wherein said permeation-barrier layer system is transparent to visible light.
29) The substrate of one of aspects 1 to 28 said permeation-barrier layer system being electrically isolating from the surface of said substrate to the surface of said starting substrate.
30) The substrate of one of aspects 1 to 29 wherein at least one layer of said permeation-barrier layer system is electrically isolating.
31) A layer deposition apparatus comprising:
   a substrate carrier;
   At least one inorganic material layer deposition station comprising at least one PVD layer deposition chamber and/or at least one ALD layer deposition chamber, each comprising a source of an inorganic material;
   at least one polymer deposition station comprising at least one plasma polymerizing chamber with a feed-line system for monomer feeding and a plasma source;
   a control unit constructed to control intermittent exposure of said substrate carrier to the deposition effect from said inorganic material layer deposition station and from said at least one polymer deposition station.
32) the layer deposition apparatus of aspect 31 comprising at least one cooling station.
33) The layer deposition apparatus of one of aspect 31 or 32 at least one inorganic material layer deposition station comprising at least one ALD layer deposition chamber, comprising a gas supply arrangement operationally flow-connected to at least a precursor reservoir containing a precursor and to a reactive gas reservoir containing a reactive gas.
34) The layer deposition apparatus of one of aspect 31 to 33 at least one inorganic material layer deposition station comprising at least two ALD layer deposition chambers, one of said at least two ALD layer deposition chambers comprising a gas supply arrangement operationally connected to a precursor reservoir containing a precursor, the other of said ALD deposition chambers comprising a gas supply arrangement operationally connected to a reactive gas reservoir, containing a reactive gas.
35) The layer deposition apparatus of one of aspect 33 or 34 a precursor gas from said precursor reservoir containing at least one of silicon and of a metal.
36) The layer deposition apparatus of aspect 35 said metal being at least one of aluminum, tantalum, titanium, hafnium.
37) The layer deposition apparatus of one of one of aspects 33 to 36 said reactive gas containing at least one of oxygen and of nitrogen.
38) The layer deposition apparatus of one of aspects 31 to 37 at least one inorganic material layer deposition station comprising at least one ALD layer deposition chamber comprising a laser source, a gas supply arrangement operationally flow-connected to at least a precursor reservoir containing a precursor and to a reactive gas reservoir containing a reactive gas.
39) The layer deposition apparatus of one of aspect 31 to 38 at least one inorganic material layer deposition station comprising at least two ALD layer deposition chambers, one of said at least two ALD layer deposition chambers comprising a gas supply arrangement operationally connected to a precursor reservoir containing a precursor, the other of said ALD deposition chambers comprising a laser source and a gas supply arrangement operationally connected to a reactive gas reservoir, containing a reactive gas.
40) The layer deposition apparatus of one of aspect 31 to 39 at least one inorganic material layer deposition station comprising at least one PVD layer deposition chamber.
41) The layer deposition apparatus of aspect 41 said PVD layer deposition chamber being a sputter layer deposition chamber.
42) The layer deposition apparatus of aspect 40 said PVD layer deposition chamber being an evaporation chamber, or an electron beam evaporation chamber.
43) The layer deposition apparatus of one of aspects 40 to 42 said PVD layer deposition chamber having a solid material source of at least one metal or metal alloy or of an oxide or of a nitride or of an oxynitride of such metal or metal alloy.
44) The layer deposition apparatus of one of aspects 31 to 43 wherein at least one inorganic material layer deposition station and at least one polymer deposition station are distant from each other and said substrate carrier is controllably movable from one of these stations to the next one of these stations, preferably in a vacuum environment.
45) The layer deposition apparatus of one of aspects 31 to 44 wherein at least one PVD layer deposition chamber and/or at least one ALD layer deposition chamber comprises a for deposition operation controllably sealable and for substrate handling openable deposition space, and a pumping port abutting in said controllably sealable and openable deposition space.
46) The layer deposition apparatus of one of aspects 31 to 45 wherein at least one plasma polymerizing chamber with a feed-line system for monomer feeding and with a plasma source comprises a for layer deposition operation controllably sealable and for substrate handling openable deposition space and a pumping port abutting in said controllably sealable and openable deposition space.
47) The layer deposition apparatus of one of aspects 31 to 46 wherein at least one inorganic material layer deposition station and at least one polymer deposition station perform deposition in a common deposition area.
48) The layer deposition apparatus of one of aspect 31 to 47 comprising, along a linear, or along a generically curved or along a circular movement path of said substrate carrier, a sequence of more than one pair of an inorganic material layer deposition station and of a polymer deposition station.
49) The layer deposition apparatus of one of aspect 31 to 48 comprising, along a linear or along a generically curved or along a circular movement path of said substrate carrier, a sequence of an inorganic material layer deposition station and of a polymer deposition station directly subsequent the inorganic material layer deposition station.
50) The layer deposition apparatus of one of aspects 31 to 49 comprising a cooling station directly succeeding an inorganic material layer deposition station.
51) The layer deposition apparatus of one of aspects 31 to 50 being a vacuum apparatus comprising at least one input load lock and at least one output load lock or at least one bidirectional input/output load lock.
52) The layer deposition apparatus of one of aspects 31 to 51, wherein at least one inorganic material layer deposition station and at least one polymer deposition station are depositing onto a common deposition area and the control unit is constructed to intermittently enable/disable the addressed stations.
53) The layer deposition apparatus of one of aspects 31 to 52, wherein at least one inorganic material layer deposition station and at least one polymer deposition station are depositing into mutually distant areas and the control unit is constructed to control a movement of said substrate carrier between said areas.
54) The layer deposition apparatus of one of aspects 31 to 53 constructed to enable deposition by both, an inorganic material layer deposition station and a polymer deposition station simultaneously in a common deposition area during a controlled transition time span.
55) The layer deposition apparatus of one of aspects 31 to 54 said feed-line system being in controlled flow communication with a reservoir containing a liquid or gaseous monomer material.
56) The vacuum layer deposition apparatus of one of aspects 31 to 55 said feed-line system being in controlled flow communication with a reservoir containing a material comprising carbon.
57) The layer deposition apparatus of one of aspects 31 to 56, said feed-line system being in controlled flow communication with a reservoir containing a material comprising silicon.
58) The layer deposition apparatus of one of aspects 31 to 57 said feed-line system being in controlled flow communication with a reservoir containing at least one of tetramethylsilane (TMS), hexamethyldisiloxan (HMDS(O)), hexamethyldisilazan (HMDS(N)), tetraethylorthosilan (TEOS), acetylene, ethylene.
59) The layer deposition apparatus of one of aspects 31 to 58 said substrate carrier being constructed to simultaneously carry more than one substrate and/or more than one starting substrate.
60) The layer deposition apparatus of one of aspects 31 to 59 wherein all polymerizing chambers are plasma-polymerizing chambers.
61) The layer deposition apparatus of one of aspects 31 to 60 having at least one of the following features:
   The substrate carrier is constructed to carry a batch of substrates and/or of starting substrates;
   The substrate carrier is constructed to carry a plurality of single substrates and/or single starting substrates;
   the movement of the substrate carrier is a rotational movement around an axis remote from the substrates or starting substrates and/or around respective central axes of the substrates or starting substrates;
   the substrate carrier being provided in a vacuum environment.
62) A method of providing a permeation-barrier layer system on a starting substrate, or of manufacturing a substrate provided with a surface permeation-barrier layer system, comprising:
   a) Establishing permeation-seal by depositing by PVD and/or by ALD at least one inorganic material layer system, comprising at least one inorganic-material-containing layer, upon a starting substrate;
   b) Providing adhesion of said inorganic material layer system to said starting substrate and crack-sealing of said inorganic material layer system, by depositing a polymer material layer system comprising at least one polymer-material-containing layer, directly on said starting substrate and depositing said inorganic material layer system directly on said polymer material layer system.
63) The method of aspect 62 comprising vacuum plasma polymerizing material of said polymer-material-containing layer or of at least one of polymer-material containing layers.
64) The method of aspect 62 or 63 wherein establishing said permeation-seal comprising plasma enhanced ALD.
65) The method of one of aspects 62 to 64 at least one layer being deposited from an electrically isolating layer.
66) The method of one of aspects 62 to 65 said permeation-barrier layer system being deposited to be transparent for visible light.
67) The method of one of aspects 62 to 66, wherein the temperature at the starting substrate during said depositions does not exceed a predetermined value, which preferably does not exceed at most 150° C.
68) The method of one of aspects 62 to 67, comprising depositing a further polymer material layer system, comprising at least one polymer-material-containing layer, directly on said inorganic material layer system.
69) The method of one of aspects 62 to 68 comprising vacuum plasma polymerizing material of more than one polymer-material-containing layers.
70) The method of one of aspects 62 to 69 comprising repeating said steps a) and b).
71) The method of aspect 62 to 70 comprising depositing a further polymer material layer system, comprising at least one polymer-material-containing layer, directly on the last-deposited inorganic material layer system.
72) The method of one of aspects 62 to 71 comprising cooling said substrate after or during at least one of depositing an inorganic material layer system.
73) The method of one of aspects 62 to 72 comprising depositing an inorganic-material-containing layer of silicon oxide.
74) The method of one of aspects 62 to 73 comprising depositing in a controlled manner at least one material interface between depositing a polymer-material-containing layer and depositing an inorganic-material-containing layer, said interface being of a material which comprises polymer material of said deposited polymer-material-containing layer as well as inorganic material of said inorganic-material-containing layer.
75) The method of one of aspects 62 to 74 comprising depositing at least one polymer-material-containing layer from a gaseous or liquid material.
76) The method of one of aspects 62 to 75 comprising depositing at least one polymer-material-containing layer from a material containing carbon.
77) The method of one of aspects 62 to 76 comprising depositing at least one polymer-material-containing layer from a material containing silicon.
78) The method of one of aspects 62 to 77 comprising depositing at least one polymer-material-containing layer from one of tetramethylsilane (TMS), hexamethyldisiloxan (HMDS(O)), hexamethyldisilazan (HMDS(N)), tetraethylorthosilan (TEOS), acetylene, ethylene.
79) The method of one of aspects 62 to 78 comprising depositing at least one inorganic-material-containing layer comprising or consisting of at least one of silicon oxide, silicon nitride, aluminum oxide, aluminum nitride, titanium oxide, titanium nitride, tantalum oxide, tantalum nitride hafnium oxide or of a respective oxynitride.
80) The method of one of aspects 62 to 79 comprising depositing at least one inorganic-material-containing layer by sputtering or by evaporation or by electron beam evaporation or by ALD or by plasma enhanced ALD.
81) The method of one of aspects 62 to 80 comprising depositing at least one inorganic-material-containing layer by ALD in an ALD deposition chamber and feeding a precursor gas and a reactive gas to said ALD deposition chamber.
82) The method of one of aspects 62 to 81 comprising depositing at least one inorganic-material-containing layer by ALD in at least two subsequent ALD deposition chambers and feeding a precursor gas to the first of said at least two ALD deposition chambers and feeding a reactive gas to the second of said at least two subsequent ALD deposition chambers.
83) The method of one of aspects 81 or 82 said precursor gas containing silicon or a metal.
84) The method of aspect 83 said metal being at least one of aluminum, tantalum, titanium, hafnium
85) The method of one of aspects 81 to 84 said reactive gas containing at least one of oxygen and of nitrogen.
86) The method of one of aspects 62 to 85 comprising depositing an inorganic-material-containing layer in at least one layer deposition space, sealing said at least one deposition space during said depositing and pumping said deposition space by means of a pump directly connected to said deposition space.
87) The method of one of aspects 62 to 86 comprising depositing a polymer-material-containing layer in a layer deposition space, sealing said deposition space during said depositing and pumping said deposition space by means of a pump directly connected to said deposition space.
88) The method of one of aspects 62 to 87 comprising manufacturing said permeation barrier layer system suppressing permeation of water molecules.
89) The method of one of aspects 62 to 88 performed in vacuum.
90) The method of one of aspects 62 to 89 performed by means of an apparatus according to aspects 31 to 61.

1) A method of providing a permeation-barrier layer system on a starting substrate, or of manufacturing a substrate provided with a surface permeation-barrier layer system, comprising:
a) establishing permeation-seal by depositing by PVD and/or by ALD at least one inorganic material layer system, comprising at least one inorganic-material-containing layer, upon a starting substrate;
b) providing adhesion of said inorganic material layer system to said starting substrate and crack-sealing of said inorganic material layer system, by depositing a polymer material layer system comprising at least one polymer-material-containing layer, directly on said starting substrate and depositing said inorganic material layer system directly on said polymer material layer system.

2) The method of claim 1 comprising vacuum plasma polymerizing material of said polymer-material-containing layer or of at least one of polymer-material containing layers.

3) The method of claim 1 wherein establishing said permeation-seal comprising plasma enhanced ALD.

4) The method of claim 1 at least one layer being deposited from an electrically isolating layer.

5) The method of claim 1 said permeation-barrier layer system being deposited to be transparent for visible light.

6) The method of claim 1, wherein the temperature at the starting substrate during said depositions does not exceed a predetermined value, which preferably does not exceed at most 150° C.

7) The method of claim 1, comprising depositing a further polymer material layer system, comprising at least one polymer-material-containing layer, directly on said inorganic material layer system.

8) The method of claim 1, comprising vacuum plasma polymerizing material of more than one polymer-material-containing layers.

9) The method of claim 1 comprising repeating said steps a) and b).

10) The method of claim 1 comprising depositing a further polymer material layer system, comprising at least one polymer-material-containing layer, directly on the last-deposited inorganic material layer system.

11) The method of claim 1 comprising cooling said substrate after or during at least one of depositing an inorganic material layer system.

12) The method of claim 1 comprising depositing an inorganic-material-containing layer of silicon oxide.

13) The method of claim 1 comprising depositing in a controlled manner at least one material interface between depositing a polymer-material-containing layer and depositing an inorganic-material-containing layer, said interface being of a material which comprises polymer material of said deposited polymer-material-containing layer as well as inorganic material of said inorganic-material-containing layer.

14) The method of claim 1 comprising depositing at least one polymer-material-containing layer from a gaseous or liquid material.

15) The method of claim 1 comprising depositing at least one polymer-material-containing layer from a material containing carbon.

16) The method of claim 1 comprising depositing at least one polymer-material-containing layer from a material containing silicon.

17) The method of claim 1 comprising depositing at least one polymer-material-containing layer from one of tetramethylsilane (TMS), hexamethyldisiloxan (HMDS(O)), hexamethyldisilazan (HMDS(N)), tetraethylorthosilan (TEOS), acetylene, ethylene.

18) The method of claim 1 comprising depositing at least one inorganic-material-containing layer comprising or consisting of at least one of silicon oxide, silicon nitride, aluminum oxide, aluminum nitride, titanium oxide, titanium nitride, tantalum oxide, tantalum nitride hafnium oxide or of a respective oxynitride.

19) The method of claim 1 comprising depositing at least one inorganic-material-containing layer by sputtering or by evaporation or by electron beam evaporation or by ALD or by plasma enhanced ALD.

20) The method of claim 1 comprising depositing at least one inorganic-material-containing layer by ALD in an ALD deposition chamber and feeding a precursor gas and a reactive gas to said ALD deposition chamber.

21) The method of claim 1 comprising depositing at least one inorganic-material-containing layer by ALD in at least two subsequent ALD deposition chambers and feeding a precursor gas to the first of said at least two ALD deposition chambers and feeding a reactive gas to the second of said at least two subsequent ALD deposition chambers.

22) The method of claim 20 said precursor gas containing silicon or a metal.

23) The method of claim 22 said metal being at least one of aluminum, tantalum, titanium, hafnium.

24) The method of claim 20 said reactive gas containing at least one of oxygen and of nitrogen.

25) The method of claim 1 comprising depositing an inorganic-material-containing layer in at least one layer deposition space, sealing said at least one deposition space during said depositing and pumping said deposition space by means of a pump directly connected to said deposition space.

26) The method of claim 1 comprising depositing a polymer-material-containing layer in a layer deposition space, sealing said deposition space during said depositing and pumping said deposition space by means of a pump directly connected to said deposition space.

27) The method of claim 1 comprising manufacturing said permeation barrier layer system suppressing permeation of water molecules.

28) The method of claim 1 performed in vacuum.

29) An apparatus constructed to perform the method according to claim 1.
